(19) United States
(12) Patent Application Publication
(10) Pub. No.: US 2008/0106716 A1
(43) Pub. Date: May 8, 2008

(54) Photomask, exposure method and apparatus that use the same, and semiconductor device

(75) Inventor: Hidenori Yamaguchi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/905,979

(22) Filed: Oct. 5, 2007

(30) Foreign Application Priority Data
Oct. 5, 2006 (JP) 2006-274154

(51) Int. Cl. G03B 27/42; G03F 1/00

(52) U.S. Cl. 355/53; 430/5; 430/322; 430/319

(57) ABSTRACT

A photomask used in step-and-scan reduced projection exposure is provided with a substrate and a pattern formation area formed on the substrate. The pattern formation area has an unequal aspect dimensions and is a long rectangular shape in a scan direction. A first pattern width in the scan direction of the pattern formation area is greater than a lens width of a reduced projection optical system, and a second pattern width in the direction orthogonal to the scan direction of the pattern formation area is equal to or less than the lens width of the reduce projection optical system. The photomask further has a mask size indicator formed in a periphery area of the substrate. The mask size indicator indicates information related to aspect dimensions of the pattern formation area.

### TECHNICAL FIELD

The present invention relates to a photomask that is capable of forming a mask pattern. The present invention also relates to a scanning exposure method and apparatus that use the photomask, and to a semiconductor device manufactured using the photomask.

### BACKGROUND OF THE INVENTION

A stepper is widely used as a reduced projection exposure apparatus for transferring a microcircuit pattern onto a resist or another photosensitive material formed on a semiconductor wafer. The stepper is a step-and-repeat exposure apparatus that comprises an illumination optical system 41 having a beam source, a photomask 42, and a reduced projection optical system 43, as shown in FIG. 12A. In a stepper, a circuit pattern 42a on a photomask 42 is reduced and projected onto the surface of a wafer 44, and the pattern is transferred onto the wafer 44. When a one-shot exposure is completed, the stage on which the wafer 44 is mounted is stepped by a prescribed amount and the wafer 44 is exposed again. This procedure is repeated until the entire wafer 44 has been exposed.

With more highly integrated semiconductor devices in recent years, there is an ever greater demand for microfabrication for wafers. Also, chip sizes have increased and projection lenses having a large diameter and high NA (numeric aperture) are needed for the steppers. In a stepper, however, the size of the exposable field (exposure field) covered in a single shot depends greatly on the diameter and aberration of the projection lens, and it has become difficult to assure a wider exposure field while maintaining high resolution because lens aberration increases as the diameter of the lens increases.

In view of the above, high-resolution step-and-scan exposure apparatuses that have a wide exposure field have recently been used (Japanese Laid-open Patent Application No. H09-167735). These exposure apparatuses are referred to as “scanners,” and are further provided with a blind 46 for forming a slitted illumination area. A single exposure is carried out by synchronously scanning the photomask 42 and wafer 44 at a prescribed velocity in accordance with the reduced projection magnification of the reduced projection optical system 43, as shown in FIG. 12B. When a single scan exposure is completed, the stage on which the wafer is mounted is stepped by a prescribed amount and exposed again. The entire wafer is exposed by repeating this procedure. Since only the portion of the lens having low aberration is used in the scanner, the exposure field can be considerably increased in the lengthwise direction of the slits, and a large exposure field can be assured as a result. A pattern can therefore be transferred having greater detail than a stepper that simultaneously exposes the entire surface of the chips.

When a wafer is processed using a conventional stepper or scanner, a photomask on which a circuit pattern enlarged by a factor of 4 or 5 is formed is used in accordance with the lens magnification of the reduced projection optical system. In particular, since the circuit pattern must be formed so that an area that can be exposed in a single shot will fit into the diameter of the projection lens, a photomask having a square pattern formation area 42b such as that shown in FIG. 13A is used. A rectangular pattern formation area 42c such as that shown in FIG. 13B may also be used as long as the projection lens included in the reduced projection optical system 43 can accommodate the area. In this case, however, there is a considerable amount of wasted area that is not used as a pattern formation area, and since the exposure field cannot be maximally utilized, a square pattern formation area is often adopted in practice.

A photomask for a scanner follows the external shape of a photomask for a stepper and has a square pattern formation area 42d, as shown in FIG. 14. However, there is no problem even if the width W_{Y} in the lengthwise direction of the pattern formation area 42d extends beyond the projection lens included in the reduced projection optical system 43 as long as the width W_{X} in the direction orthogonal to the scan direction of the pattern formation area 42d is no more than the diameter of the projection lens. For this reason, in a photomask for a scanner, an exposure field that is wider than the photomask for a stepper can be obtained by setting the width W_{X} of the pattern formation area 42d to be substantially equal to the diameter of the projection lens 43.

With a conventional photomask 50, the aspect dimensions of an area (pattern formation area) 51 in which a mask pattern can be formed are set to be the same width W₀, as shown in FIG. 15. A plurality of single-chip patterns 52 is imposed within the square pattern formation area 51 in accordance with the lens magnification (×4) of the reduced projection optical system, whereby the exposure field is improved. The photomask 50 in FIG. 15, for example, has mask patterns 52a through 52d for four chips.

However, it has become difficult to efficiently arrange a pattern having a desired number of chips in a photomask due to a greater variety of semiconductor devices and larger chip sizes. Depending on the product, the amount of wasted space in which a mask pattern is not formed increases and the pattern formation area 51 is used inefficiently. For this reason, there is a problem in that the number of steps is increased and the exposure throughput is reduced in the wafer exposure process.

### SUMMARY OF THE INVENTION

It is therefore an object of the present invention to provide a photomask that can improve exposure throughput, and can thereby reduce the number of exposure apparatuses and reduce manufacturing costs.

Another object of the present invention is to provide a step-and-scan exposure method and exposure apparatus that can form a high-definition pattern on a wafer using such a photomask.

Yet another object of the present invention is to provide a semiconductor device manufactured using such a photomask.

The above and other objects of the present invention can be accomplished by a photomask used in step-and-scan reduced projection exposure, comprising a substrate and a pattern formation area formed on the substrate, wherein the pattern formation area has an unequal aspect dimensions and is a long rectangular shape in a scan direction.

Preferably, in the present invention, the width in the scan direction of the pattern formation area is greater than the lens width of a reduced projection optical system, and the width in the direction orthogonal to the scan direction of the pattern formation area is equal to or less than the lens width of the reduce projection optical system.

Preferably, in the present invention, the photomask further comprises a mask size indicator formed in a periphery area of the substrate, wherein the mask size indicator indicates information related to the aspect dimensions of the pattern formation area.

Preferably, a plurality of single-chip patterns are imposed in at least the scan direction of the pattern formation area. In this case, the photomask of the present invention may be an ordinary binary photomask, or may be an attenuated, alternative, or chromeless phase shift mask.

The above and other objects of the present invention can also be accomplished by an exposure method for exposing a wafer by using a reduced projection exposure system, comprising the steps of: providing a photomask that has a rectangular pattern formation area having an unequal aspect dimensions and being a long rectangular shape in a scan direction in which a plurality of single-chip patterns are imposed in at least the scan direction; and exposing the wafer in the scan direction by causing relative movement between the photomask and the wafer.

Preferably the exposure method of the present invention further comprises a scan distance determination step for determining a scan distance of the photomask based on a mask size indicator included in the photomask.

The above-described objects of the present invention can also be achieved by an exposure apparatus that exposes a wafer via a step-and scan method using a photomask that has a rectangular pattern formation area having an unequal aspect dimensions and being a long rectangular shape in a scan direction in which a plurality of single-chip patterns are formed in at least the scan direction, comprising: an illumination optical system for illuminating a slitted beam onto the photomask; a reduced projection optical system for reducing and projecting on the wafer the beam that has passed through the photomask; and a scan exposure system for causing relative movement between the photomask and the wafer in the scan direction.

The above and other objects of the present invention can also be accomplished by a semiconductor device manufactured using the above-described photomask.

In accordance with the present invention, it is possible to provide a photomask that can improve exposure throughput and thereby reduce the number of exposure apparatuses and reduce manufacturing costs.

In accordance with the present invention, a step-and-scan exposure method and exposure apparatus that can form a high-definition pattern on a wafer using such a photomask can be provided.

In accordance with the present invention, a high-performance semiconductor device manufactured using such a photomask can be provided.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic plan view showing the configuration of a photomask according to a preferred embodiment of the present invention;

FIG. 2 is a cross-sectional view of the photomask;

FIG. 3 is a schematic plan view showing the configuration of a photomask 14 on which a mask pattern has been drawn;

FIG. 4 is a schematic partial cross-sectional view showing a portion of the pattern formation area 12 on the photomask 14;

FIG. 5 is a schematic plan view showing the OPC mask pattern;

FIG. 6A is a schematic cross-sectional view showing the half tone type phase shift mask pattern;

FIG. 6B is a schematic cross-sectional view showing the Levenson-type phase shift mask pattern;

FIG. 7 is a schematic perspective view showing the configuration of a scanner 20 in which the photomask 14 can be used;

FIG. 8 is a flow-chart showing the sequence for scanning and exposing the wafer using the scanner 20;

FIG. 9 is a schematic diagram showing the configuration of the exposure apparatus according to another embodiment of the present invention;

FIG. 10 is a schematic diagram showing the configuration of the exposure apparatus according to yet another embodiment of the present invention;

FIG. 11 is a schematic diagram that describes the principle of the off-axis illumination;

FIG. 12A is a schematic diagram showing a prior step and repeat type projection exposure system (stepper);

FIG. 12B is a schematic diagram showing a prior step and scan type projection exposure system (scanner);

FIG. 13A is a schematic diagram showing a relationship between a square pattern formation area of the photomask for the conventional stepper and the projection lens;

FIG. 13B is a rectangular pattern formation area of the photomask for the conventional stepper and the projection lens;

FIG. 14 is a schematic diagram showing a relationship of the pattern formation area of the prior photo mask for scanner and projection lens; and

FIG. 15 is a plan view showing a structure of the prior photomask 50.

### DESCRIPTION OF THE PREFERRED EMBODIMENTS

Preferred embodiments of the present invention will now be described in detail with reference to the accompanying drawings.

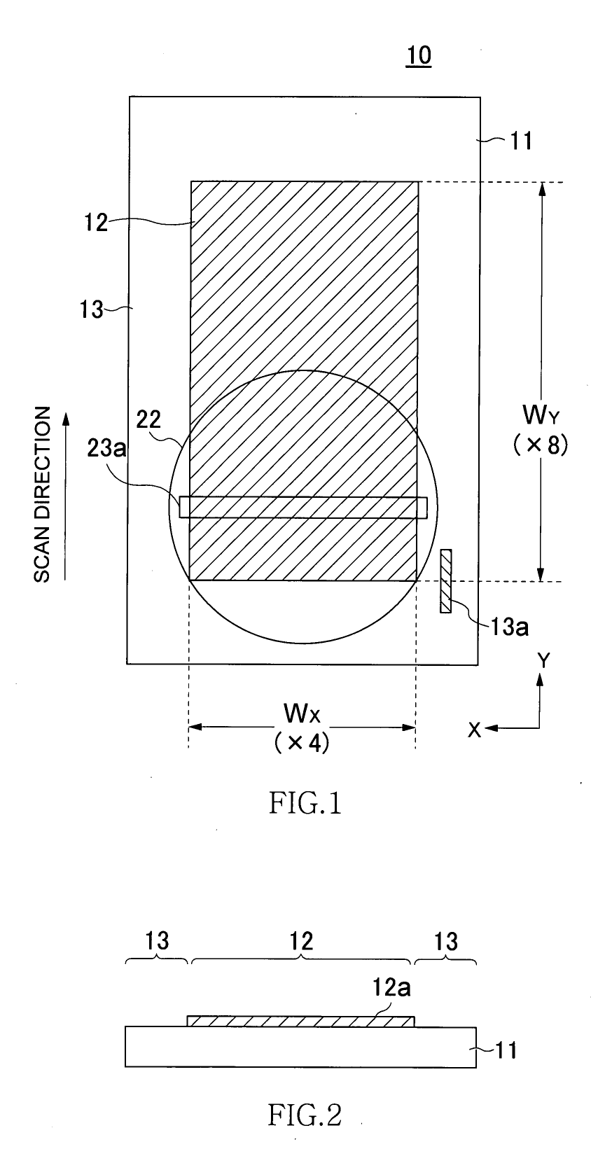

FIG. 1 is a schematic plan view showing the configuration of a photomask according to a preferred embodiment of the present invention. FIG. 2 is a cross-sectional view of the photomask.

The photomask 10 is referred to as a mask blank, is an original prior to having a mask pattern drawn thereon, and is composed of a substrate 11, a pattern formation area 12 set on the substrate 11, and an outside exposure area (recto area) 13 as a blank portion set in the periphery of the pattern formation area 12, as shown in FIG. 1. The substrate 11 is composed of a transparent quartz substrate or a glass substrate. The pattern formation area 12 is formed by uniformly covering the surface of the substrate 11 with chromium (Cr) or another light-blocking film 12a, as shown in FIG. 2.

The pattern formation area 12 has unequal aspect dimensions and is a long rectangular shape in the scan direction (Y direction). The width W_{X} in the direction orthogonal to the lengthwise direction of the pattern formation area 12 is set to be equal to or less than the width of the lens 22 and slit 23a of the reduced projection optical system. In contrast, the width W_{Y} in the lengthwise direction of the pattern formation area 12 is not particularly limited and may be made to be sufficiently greater than the width W_{X}. For this reason, in the present embodiment, the width W_{Y} in the lengthwise direction is set to be about twice that of the width W_{X} in the direction orthogonal thereto. Since the pattern formation area 12 is scanned in the Y direction, there is no particular problem if the width W_{Y} in the lengthwise direction of the pattern formation area 12 is made sufficiently greater, and patterns can be formed at high resolution in the same manner as a conventional photomask having equal aspect dimensions.

Mask size indicator 13a, which is information related to the aspect dimensions of the pattern formation area 12, is recorded in the outside exposure area 13 of the photomask 10. The outside exposure area 13 is generally used as a handling area or a formation area for alignment marks. In the present embodiment, this area is used as an area for recording the mask size indicator 13a, and the mask size indicator 13a itself acts as a alignment mark. The mask size indicator 13a is recorded, for example, as a number, code, barcode, or another format. Conventionally, the aspect dimensions of the pattern formation area 12 are equal and the scan distance of the wafer is unambiguously decided, but with the photomask 10 of the present embodiment, the width W_{Y} in the scan direction of the pattern formation area 12 is sufficiently wide and the width can be freely set, so the scanner therefore reads the mask size indicator 13a to thereby allow the scan distance of the wafer to be determined.

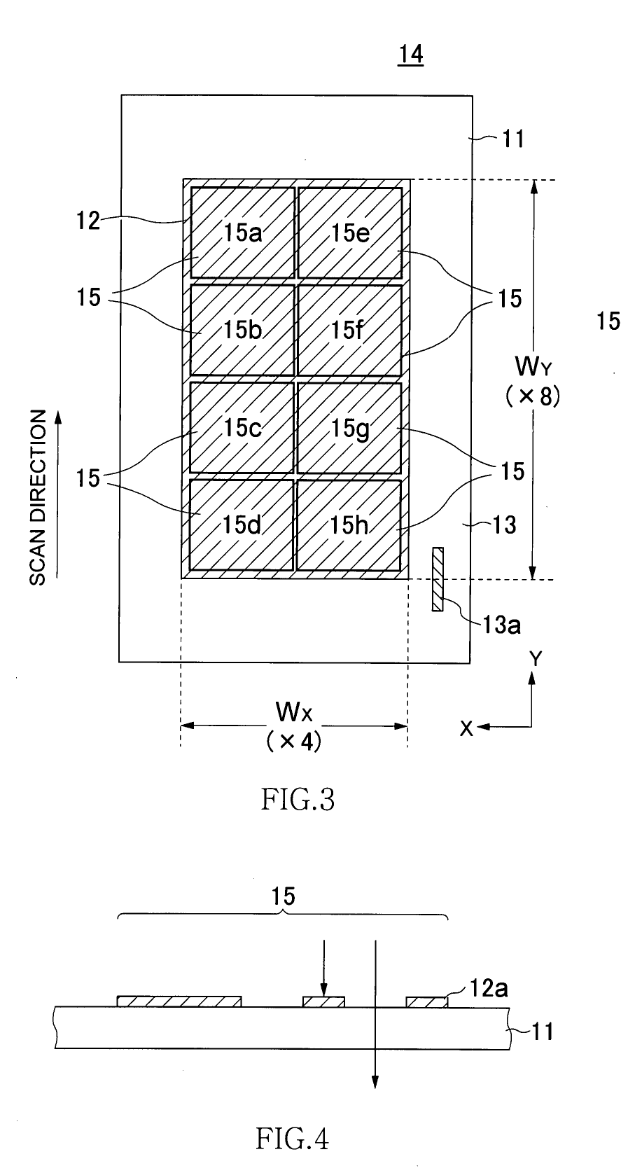

FIG. 3 is a schematic plan view showing the configuration of a photomask 14 on which a mask pattern has been drawn. FIG. 4 is a schematic partial cross-sectional view showing a portion of the pattern formation area 12 on the photomask 14.

As shown in FIG. 3, the photomask 14 of the present embodiment has an eight-chip mask pattern 15 (15a through 15h) formed in the pattern formation area 12. The mask pattern 15 is formed by partially removing the light-blocking film 12a that covers the substrate 11, as shown in FIG. 4. In other words, the surface of the substrate 11 is partially covered with chromium (Cr) or another light-blocking film 12a, and the mask pattern 15 is formed thereby. The mask pattern 15 may be a negative pattern or a positive pattern.

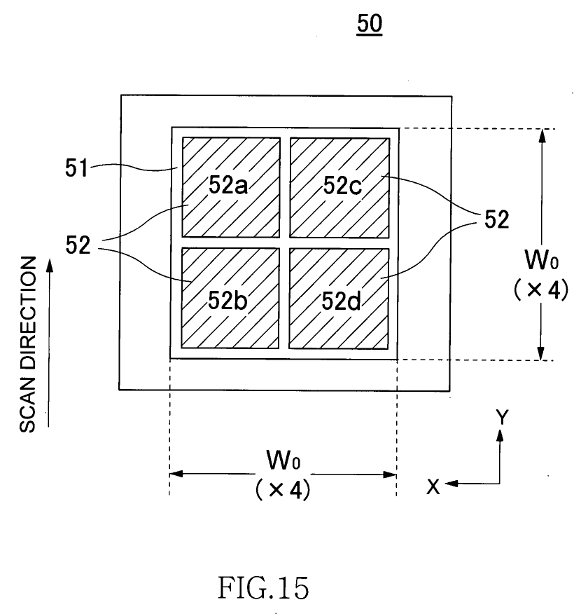

The mask patterns 15a through 15h correspond to the chips on a wafer and ordinarily have identical patterns. A conventional photomask has a pattern formation area 12 in which the aspect dimensions are equal, and only a 2×2=4-chip mask pattern, for example, can therefore be formed depending on the chip size (see FIG. 15). In the present embodiment, however, the width W_{Y} in the lengthwise direction of the pattern formation area 12 is sufficiently great, a 4×2=8-chip mask pattern can therefore be formed, and eight chips can be exposed in a single scan. In other words, a greater number of chip patterns can be provided in the lengthwise direction of the pattern formation area 12.

In this manner, the photomask 14 of the present embodiment has a rectangular pattern formation area 12. The width W_{X} in the direction orthogonal to the lengthwise direction of the pattern formation area 12 is set to be equal to or less than the width of the lens of the reduced projection optical system. However, the width W_{Y} in the lengthwise direction is set to be sufficiently large. A large number of single-chip patterns can therefore be provided in the scan direction. Thus, when scanning and exposing is carried out in the lengthwise direction using a photomask 14 that has such a pattern formation area 12, a large number of single-chip patterns can be transferred in a single scan. Therefore, the number of steps in the wafer exposure step can be reduced and exposure throughput can thereby be improved.

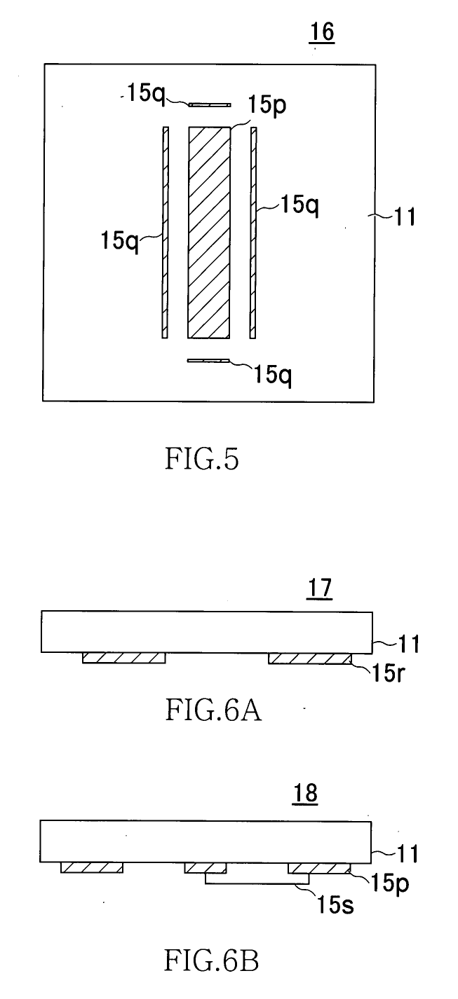

The photomask 14 of the present embodiment may be the ordinary binary photomask shown in FIGS. 3 and 4, and may be an OPC (Optical Proximity Effect Correction) mask 16 on which an OPC auxiliary pattern 15q is formed on the periphery of a mask pattern 15p such as that shown in FIG. 5. The photomask may also be a half-tone (also referred to as “attenuated”) phase shift mask 17 that uses a half light-blocking film 15r such as that shown in FIG. 6A, or may be a Levenson (also referred to as “alternative”) phase shift mask 18 that uses a thin film (phase shifter) 15s or the like such as that shown in FIG. 6B. The photomask may also be a chromeless phase shift mask in which no light-blocking films composed of chromium (Cr) are used at all. A combination of the above may also be used.

The method of exposing a wafer that uses the photomask 14 is described next.

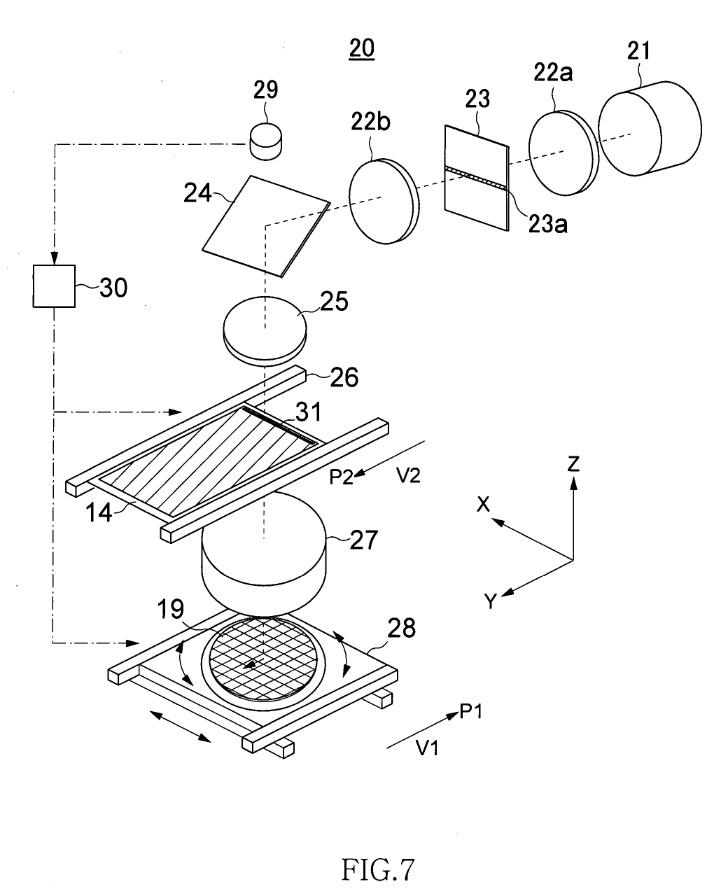

FIG. 7 is a schematic perspective view showing the configuration of a scanner 20 in which the photomask 14 can be used.

As shown in FIG. 7, the scanner 20 comprises a light source 21, lenses 22a and 22b, a blind 23 disposed between the lenses 22a and 22b, a mirror 24 for changing the travel direction of light that has passed through the lens 22b, a condenser lens 25, and a projection lens 27. The illumination optical system of the scanner 20 is composed of the light source 21, lenses 22a and 22b, blind 23, mirror 24, and condenser lens 25. The reduced projection optical system of the scanner 20 consists of the projection lens 27. The scanner 20 further comprises a photomask stage 26 on which a photomask 14 having a drawn mask pattern is mounted, a wafer stage 28 mounted with a semiconductor wafer 19 to which a resist or another photosensitive material has been applied, an imaging device 29 that can image the surface of a photomask 14, and a controller 30 for controlling the components.

Light sources that may be used for the light source 21 include g-, h-, or i-line lasers; a KrF excimer laser, an ArF excimer laser, an F₂ excimer laser, EUV, and X rays or other energy rays. The photomask 14 can be moved in the Y direction by using the photomask stage 26, and the movement velocity and the position in the Y direction are controlled by the controller 30. The wafer 19 is movable in the X and Y directions by using the wafer stage 28, and the movement velocity in the Y direction and the position in the X and Y directions are controlled by the controller 30. The wafer stage 28 has a wafer rotation mechanism, and the orientation of the wafer 19 can be rotated 360°. The photomask stage 26 and wafer stage 28 are synchronized and controlled by the controller 30. The entire mask pattern on the photomask is reduced and projected while the wafer 19 and photomask 14 are mutually synchronized and moved in the reverse direction.

The blind 23 is irradiated with light emitted from the light source 21 by way of the lens 22a. The blind 23 has a slit 23a that extends in the X direction as shown in the diagram to thereby obtain a slitted illumination area 31. The light that is limited by the blind 23 is directed to the photomask 14 by way of the lens 22b, mirror 24, and condenser lens 25. Light that has passed through the photomask 14 is transmitted by the projection lens 27 and directed to the wafer 19.

The wafer 19 is moved at a prescribed velocity V₁ in the direction indicated by the arrow P1 (the opposite direction to the scan direction). On the other hand, the photomask 14 is moved at a prescribed velocity V₂ in the opposite direction of the movement direction of the wafer 19 (i.e., the scan direction), as indicated by the arrow P2. Thus, the slitted illumination area 31 is moved in the scan direction at a scanning velocity of V₁ to scan and expose an entire prescribed exposure area on the wafer 19 by moving the wafer 19 at a prescribed velocity V₁ in the direction indicated by the arrow P1 (the opposite direction to the scan direction), while the wafer 19 is irradiated by slitted light that has passed through the photomask 14. On the other hand, the slitted illumination area 31 scans the entire mask pattern on the photomask 14, and the entire mask pattern is reduced and projected in a prescribed exposure area on the wafer 19 by moving the photomask 14 at a prescribed velocity V₂ in the opposite direction of the movement direction of the wafer 19 (i.e., the scan direction), as indicated by the arrow P2.

Since the aspect dimensions of the conventional photomask are substantially equal, the scan distance (scan time) is determined as a matter of course. However, the photomask of the present embodiment has aspect dimensions that are not equal and the width W_{Y} in the lengthwise direction is different depending on the photomask, and the scan distances are therefore different. For this reason, the mask size indicator 13a recorded in the outside exposure area 13 is read and the scan distance (scan distance) is determined from the mask size indicator 13a, whereby a photomask having arbitrary dimensions can be accommodated and a pattern having a large number of chips can be transferred in a single process.

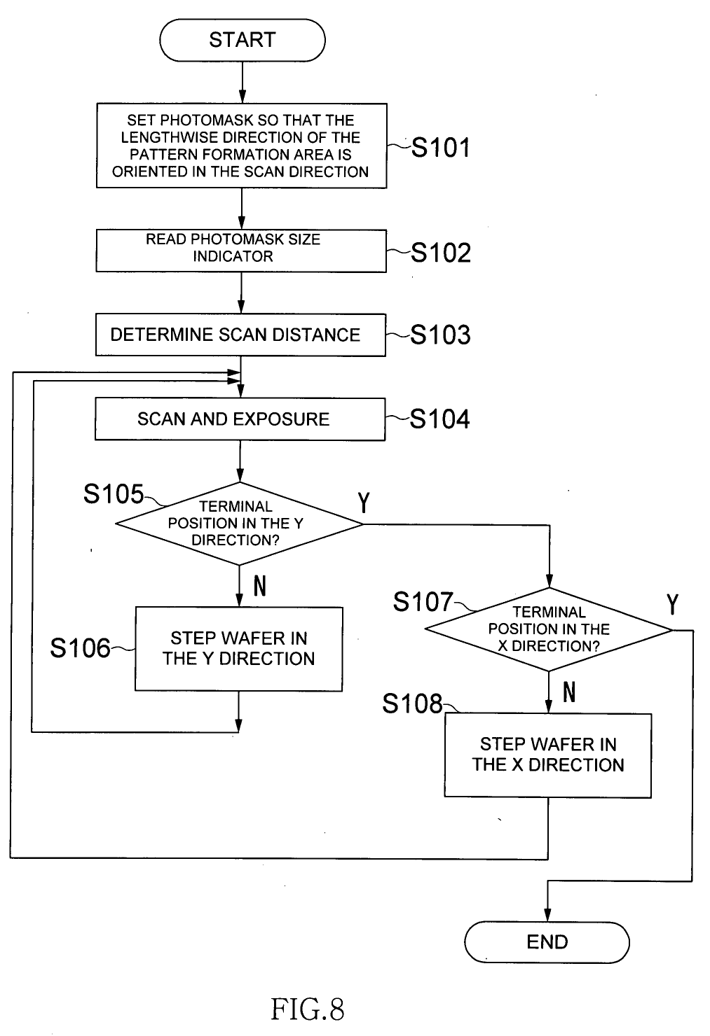

Next, the sequence for scanning and exposing the above-described wafer using the scanner 20 is described with reference to FIG. 8.

When the wafer 19 is scanned and exposed using the scanner 20 described above, the photomask 14 is first mounted on the photomask stage 26 (S101). In this case, the lengthwise direction of the photomask is set so as to be oriented in the scan direction.

The mask size indicator 13a, which is located in the outside exposure area 13 on the photomask 14, is subsequently read by the imaging device 29, the photomask 14 and wafer 19 are positioned relative to each other on the basis of the mask size indicator 13a, and the scan distance is read (S102).

Next, the movement distance of the photomask 14 is determined based on the mask size indicator 13a (S103). The movement distance of the photomask is determined based on the scan time and relative velocity (scan velocity) between the wafer 19 and the photomask 14. Since the scan velocity is ordinarily determined in advance, the scan time is actually a component that determines the movement distance of the photomask 14.

Next, the wafer 19 is scanned and exposed (S104). In scan exposure, the slitted illumination area on the wafer 19 is moved in the Y direction at a prescribed scanning velocity by moving the stage 26 and wafer stage 28 in mutually opposite directions while illuminating the photomask 14 with a slitted luminous flux. In this manner, the entire pattern on the photomask 14 is transferred onto the wafer 19 by scanning the entire photomask 14. When the entire photomask 14 is scanned, a high-definition pattern can be formed on the wafer 19, a large number of chip patterns can be transferred at the same time in a single process, and the exposure throughput can therefore be improved.

When a single scan has been completed, the wafer is moved in the Y direction by a prescribed scan distance obtained from the mask size indicator 13a, and a pattern is formed in the Y direction on the wafer by repeating the scan and exposure procedure until the terminal point in the Y direction (S105N, S106). When exposure for all of the chips in the Y direction is completed (S105Y), the wafer is moved in the X direction until the terminal position in the X direction is reached (S107N, S108), and exposure for the all of the chips on the wafer is completed by repeating the scan and exposure procedure in the Y direction (S104 through S106).

As described above, in accordance with the present embodiment, the photomask 10 has a rectangular pattern formation area 12 in which a mask pattern can be formed, the width W_{Y} in the lengthwise direction of the pattern formation area 12 is greater than the width of the lens of the reduced projection optical system, and the width W_{X} in the direction orthogonal to the lengthwise direction of the pattern formation area 12 is equal to or less than the width of the lens of the reduced projection optical system. Thus, large number of chip patterns can be formed is formed in the single scan. Also, in accordance with the photomask 14 of the present embodiment, the lengthwise direction of the pattern formation area 12 is scanned and exposed as the scan direction, whereby a pattern for a plurality of chips can be formed on a wafer in a single process and exposure throughput can be improved. Therefore, a high-performance, low-cost semiconductor device can be provided when the semiconductor device is manufactured using the photomask 14.

In accordance with the exposure method of the present embodiment, the wafer 19 is exposed using the step-and-scan method using the lengthwise direction of the pattern formation area 12 as the scan direction and using a photomask 14 on which a plurality of chip patterns is formed in the rectangular pattern formation area 12, and a pattern for a plurality of chips can therefore be formed on the wafer 19 in a single process and the exposure throughput can be improved. Therefore, a high-performance and low-cost semiconductor device can be provided when the semiconductor device is manufactured using the photomask 14.

The photomask of the present invention may be applied to various scan exposure methods.

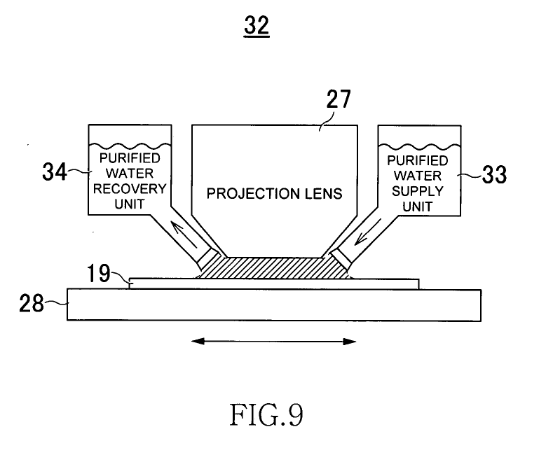

FIG. 9 is a schematic diagram showing the configuration of the exposure apparatus according to another embodiment of the present invention.

The immersion exposure method is adopted in the exposure apparatus 32. The exposure apparatus 32 comprises a purified water supply unit 33 for feeding purified water between the projection lens 27 and wafer 19 mounted on the wafer stage 28, and a purified water recovery unit 34 for recovering the purified water, as shown in FIG. 9. A beam that attempts to pass through the projection lens 27 at a sharp angle is ordinarily reflected at the boundary surface with the air. Therefore, the resolution does not increase, but when water is added, the beam is bent at the boundary surface of the water, the focus point can be reached, and the focus depth can be improved. In accordance with the immersion exposure method, very detailed microfabricating to a circuit line width of 45 nm is made possible because an equivalent wavelength (λ/n) of 134 nm can be achieved even if an ArF excimer laser having a wavelength of 193 nm is used as a beam source.

The photomask 14 of the present embodiment can be used because the step-and-scan exposure method for carrying out exposures while moving the wafer 19 and the photomask 14 in a relative manner is adopted in the exposure apparatus 32, and a pattern for a plurality of chips can be formed in a single scan. In particular, a pattern with a higher resolution can be obtained in comparison with the scanner 20 because the immersion exposure method is adopted.

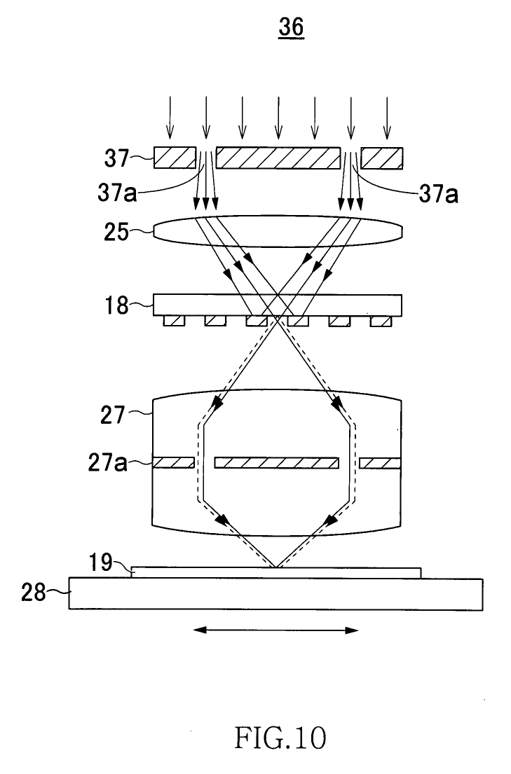

FIG. 10 is a schematic diagram showing the configuration of the exposure apparatus according to yet another embodiment of the present invention.

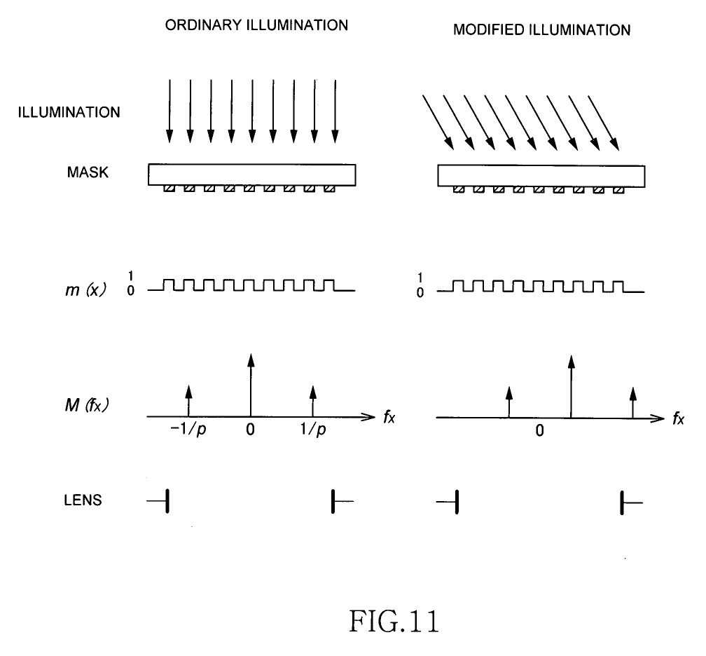

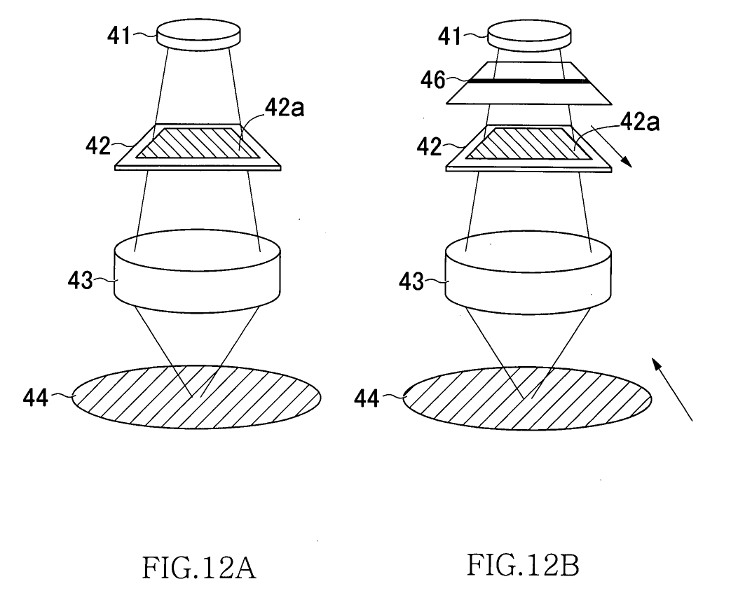

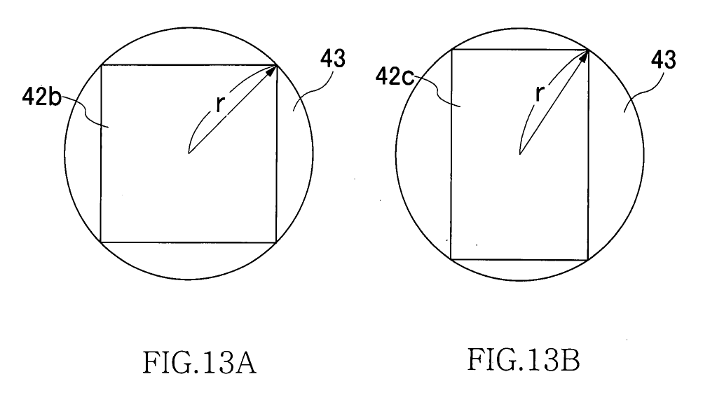

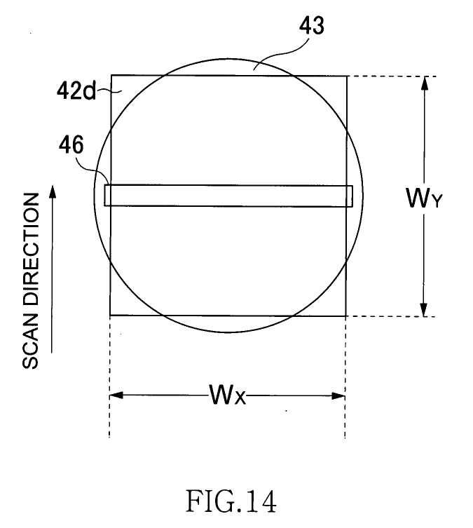

As shown in FIG. 10, a modified illumination (off-axis illumination) method is adopted in the exposure apparatus 36, and the exposure apparatus features a spacial filter 37 for implementing off-axis illumination. The spacial filter 37 is disposed in the Fourier transform plane of the illumination optical system. A beam emitted from the light source passes through the transmission window 37a in the spacial filter 37 and enters the condenser lens 25. In other words, the position of illumination in the case that exposure is carried out using off-axis illumination is offset from the optical axis of the optical system. Thus, with off-axis illumination, a 0 order beam and ±1 order beam travel while offset from the center of the optical axis of the optical system, as shown in FIG. 11. Therefore, a beam that is far from the center of the optical axis (+1 order beam, in this case) is not used, and only the two components proximate to the optical axis (0 and −1 order beams) are used. The DOF focal depth of a compact pattern is thereby increased, and the range of conditions in which drawing can be performed is expanded.

The exposure apparatus 36 which uses the modified illumination method is also capable of adopting a step-and-scan method in which a wafer 19 is moved and exposed. Therefore, the photomask 14 of the present embodiment can be used and a pattern for a plurality of chips can be formed with a single scan. In particular, a pattern with a higher resolution can be obtained in comparison with the scanner 20 described above because the modified illumination method is adopted. A pattern with a higher resolution can be obtained if the modified illumination method and the immersion exposure method described above are combined.

The present invention has thus been shown and described with reference to specific embodiments. However, it should be noted that the present invention is in no way limited to the details of the described arrangements but changes and modifications may be made without departing from the scope of the appended claims.

For example, in the present embodiment, the case was described in which an 8-chip pattern is formed within the pattern formation area 12, as shown in FIG. 3, but the number of chips within the pattern formation area 12 is not particularly limited, and the number may be suitably set in accordance with the size of the chips. For example, if the chip size is small, a 3 to 4-chip pattern can be disposed in the X direction and 6 to 8 chips can be disposed in the Y direction, or a greater number may also be used. If the chip size is very large, a single-chip pattern can be disposed in the X direction and two chips may be disposed in the Y direction, or a greater number may also be used. If a very long photomask is used on which the same number of chip patterns as the number that is to be formed on the wafer is formed in the lengthwise direction, exposure throughput can be greatly increased because stepping is carried out only in the X direction and no stepping is carried out in the Y direction.

In the embodiments described above, a pattern formation area 12 and outside exposure area 13 are formed on the substrate 11 constituting the photomask 10, but the present invention in not limited to such a configuration, and the pattern formation area 12 may be formed over the entire surface of the substrate 11. In this case, the photomask may be mounted on another support substrate and the support substrate may be used as the outside exposure area to record the photomask size information.

In the embodiments described above, the reduced projection optical system of the scanner 20 is configured with a projection lens 27, but the present invention in not limited to such a configuration, and the configuration may also be one in which only mirrors and other reflective optical systems are used.

What is claimed is:

1. A photomask used in step-and-scan reduced projection exposure, comprising a substrate and a pattern formation area formed on the substrate,
wherein the pattern formation area has an unequal aspect dimensions and is a long rectangular shape in a scan direction.

2. The photomask as claimed in claim 1, wherein a first pattern width in the scan direction of the pattern formation area is greater than a lens width of a reduced projection optical system, and a second pattern width in the direction orthogonal to the scan direction of the pattern formation area is equal to or less than the lens width of the reduce projection optical system.

3. The photomask as claimed in claim 1, further comprising a mask size indicator formed in a periphery area of the substrate, wherein the mask size indicator indicates information related to aspect dimensions of the pattern formation area.

4. The photomask as claimed in claim 1, wherein a plurality of single-chip patterns are imposed in at least the scan direction of the pattern formation area.

5. The photomask as claimed in claim 1, wherein the photomask is a binary type.

6. The photomask as claimed in claim 1, wherein the photomask is one of an attenuated type, an alternative type, and a chromeless phase shift type.

7. An exposure method for exposing a wafer by using a reduced projection exposure system, comprising the steps of:
providing a photomask that has a rectangular pattern formation area having an unequal aspect dimensions and being a long rectangular shape in a scan direction in which a plurality of single-chip patterns are imposed in at least the scan direction; and
exposing the wafer in the scan direction by causing relative movement between the photomask and the wafer.

8. The exposure method as claimed in claim 7, further comprises a scan distance determination step for determining a scan distance of the photomask based on a mask size indicator included in the photomask.

9. The exposure method as claimed in claim 7, wherein a first pattern width in the scan direction of the pattern formation area is greater than a lens width of the reduced projection optical system, and a second pattern width in the direction orthogonal to the scan direction of the pattern formation area is equal to or less than the lens width of the reduce projection optical system.

10. The exposure method as claimed in claim 7, wherein the photomask is a binary type.

11. The exposure method as claimed in claim 7, wherein the photomask is one of an attenuated type, an alternative type, and a chromeless phase shift type.

12. An exposure apparatus that exposes a wafer via a step-and scan method using a photomask that has a rectangular pattern formation area having an unequal aspect dimensions and being a long rectangular shape in a scan direction in which a plurality of single-chip patterns are formed in at least the scan direction, comprising:
an illumination optical system for illuminating a slitted beam onto the photomask;
a reduced projection optical system for reducing and projecting on the wafer the beam that has passed through the photomask; and
a scan exposure system for causing relative movement between the photomask and the wafer in the scan direction.

13. A semiconductor device manufactured using a photomask used in step-and-scan reduced projection exposure, wherein the photomask comprising a substrate and a pattern formation area formed on the substrate,
wherein the pattern formation area has an unequal aspect dimensions and is a long rectangular shape in a scan direction.
